(19) United States
(12) Patent Application Publication
(10) Pub. No.: US 2018/0170754 A1
(43) Pub. Date: Jun. 21, 2018

(54) AQUEOUS-BASED METHOD OF PREPARING METAL CHALCOGENIDE NANOMATERIALS

(71) Applicant: Baoshan Iron & Steel Co., Ltd., Shanghai (CN)

(72) Inventors: Zhen Li, Wollongong (AU); Chao Han, Wollongong (AU); Shixue Dou, Wollongong (AU)

(21) Appl. No.: 15/579,141

(22) PCT Filed: Jun. 1, 2015
(86) PCT No.: PCT/CN2015/080464

§ 371 Date: Dec. 1, 2017

(51) Int. Cl. C01B 19/00; C01G 3/12; C01G 3/02; C01G 29/00; C01G 21/21; C01G 5/00; C01G 30/00; C01G 19/00; H01L 35/34; H01L 35/26

(52) U.S. Cl. CPC C01B 19/007; H01G 9/2022; C01G 3/02; C01G 29/00; C01G 21/21; C01G 5/00; C01G 30/008; C01G 19/00; C01B 19/002; C01G 5/006; H01L 35/34; H01L 35/26; C01P 2004/13; C01P 2004/24; C01P 2006/32; C01P 2006/40; C01P 2004/03; C01P 2002/72; C01P 2004/04; C01G 3/12

(57) ABSTRACT

Provided is a method for producing metal chalcogenide nanomaterials, comprising the steps of forming an aqueous solution of a chalcogen precursor, a reducing agent and a metal salt; mixing the aqueous solution for a duration of time at a reaction temperature of between about 10° C. to about 40° C., inclusively; and separating the produced metal chalcogenide nanomaterials from the aqueous solution. Also provided is a method of converting metal chalcogenide nanoparticles into metal chalcogenide nanotubes or nanosheets, comprising the steps of forming an aqueous mixture of a chalcogen precursor, a reducing agent and the metal chalcogenide nanoparticles in water; and forming the nanotubes or nanosheets by stirring or not stirring the aqueous mixture, respectively.

### TECHNICAL FIELD

The present invention generally relates to metal chalcogenide nanomaterials, and more specifically to a method or process of synthesizing or preparing metal chalcogenide nanomaterials. In further specific examples, the metal chalcogenide nanomaterials are formed or provided as nanostructures, such as nanoparticles, nanowires, nanotubes and/or nanosheets. Such chalcogenide nanomaterials find application in, for example, conversion of heat and/or light into electricity.

### BACKGROUND

Growing energy demands, concerns over climate change and depleting fossil fuel resources have led to a concerted effort to efficiently use energy through advanced technologies, of which green thermoelectric (TE) and photovoltaic (PV) technologies have attracted considerable attention, because over 60% of energy produced is wasted as heat (see A. J. Simon and R. D. Belles, Lawrence Livermore National Labs, 2011, LLNL-MI-410527.), and solar energy is abundant and sustainable.

Direct conversion of huge amounts of waste heat into electricity would significantly relieve energy and environmental issues. However, a major drawback of current TE technology is the low conversion efficiency (typically ˜5%) due to the lack of high-performance TE materials. The performance of TE materials is characterized by a dimensionless parameter of merit (ZT) according to the equation:

$$Z = \frac{{S}^{2} σ}{κ} \qquad ( 1 )$$

where S, σ, T and κ are the Seebeck coefficient, electrical conductivity, absolute temperature, and thermal conductivity, respectively.

Equation 1 clearly shows that the key to achieving a high ZT is to increase electrical conductivity and Seebeck coefficient, while reducing thermal conductivity. However, achieving this is very challenging for bulk thermoelectric materials because these parameters are interdependent and so changing one alters the others (see Z. Li, Q. Sun, X. D. Yao, Z. H. Zhu and G. Q. Lu, J. Mater. Chem., 2012, 22, 22821-22831.)

In recent years, significant progress has been made in improving the ZT of various TE materials by application of nanotechnology. Improvement of thermoelectric performance arising from nano effects are mainly due to a decrease in the thermal conductivity arising from increased phonon scattering and quantum confinement effects. One example is lead telluride (PbTe), which has been known for several decades with the best reported ZT being 1 at 750 K, whereas after introduction of nanoprecipitates by chemical doping (e.g. Sr- and Na-codoped PbTe, Ag- and Sb-codoped PbTe) the ZT has been improved to 2.2 at 915 K (see K. Biswas, J. He, I. D. Blum, C.-I. Wu, T. P. Hogan, D. N. Seidman, V. P. Dravid and M. G. Kanatzidis, Nature, 2012, 489, 414-418.) The lead telluride (PbTe) analogues of lead sulfide (PbS) and lead selenide (PbSe) also show a ZT over 1 or approaching 2 after introduction of nanoprecipitates, e.g. the nanocomposites of PbS—Bi₂S₃ (or Sb₂S₃, SrS and CaS) exhibit a ZT of 1.3 at 923 K.

However, these lead chalcogenide nanocomposites were prepared through solid state reactions at high temperature under vacuum, following a quenching process. Similarly, copper- and silver-based chalcogenides are promising in thermoelectrics and can be prepared by solid state reactions at high temperature. For example, cuprous selenide (Cu₂₋ₓSe) prepared at 1050° C. has the highest ZT of 1.6 at 1000 K among the bulk TE materials (see H. Liu, X. Shi, F. Xu, 1. Zhang, W. Zhang, L. Chen, Q. Li, C. Uher, T. Day and G. J. Snyder, Nat. Mater., 2012, 11, 422-425.)

In addition to nanocomposites generated from solid state reactions, there are some reports on the thermoelectric properties of solution-processed metal chalcogenide nanostructures such as nanoparticles and nanowires. These nanostructures are either prepared by a solvothermal approach at high temperature under protection of an inert atmosphere, or by a hydrothermal approach in sealed reactors such as autoclaves. Therefore, such nanocomposites are not suitable for practical application due to a complicated preparation process being required and associated high cost.

In known examples, bismuth telluride (Bi₂Te₃) has been used in low-temperature thermoelectric generators which have been commercialized. Copper chalcogenides have been also used in solar cells, lithium (or sodium) ion batteries, optical filters, window materials, etc. Lead chalcogenides (e.g. PbTe) has been investigated for thermoelectric application for more than 20 years.

Introduction or use of particular nanostructures is an important strategy to improve performance and broaden applications, as nanoscale effects not only influence intrinsic characters, but also can induce some unique properties. An example is nanoscale cuprous chalcogenides, which exhibit localized intensive plasmonic absorption, or photoluminescence in the near-infrared window, and can be used for photoacoustic imaging, phototherapy and near-infrared labelling and imaging. In addition, their superionic property arising from the fast movement of Cu⁺ ions can significantly decrease the thermal conductivity. The unique liquid-like behaviour of Cu⁺ ions together with excellent electrical conductivity leads to outstanding thermoelectric performance of cuprous chalcogenides, which has been proved in bulk non-stoichiometric cuprous selenide (Cu₂₋ₓSe) with a figure of merit (ZT) of 1.6 at 1000 K (see H. Liu, X. Shi, F. Xu, 1. Zhang, W. Zhang, L. Chen, Q. Li, C. Uher, T. Day and G. J. Snyder, Nat. Mater., 2012, 11, 422-425). Polycrystalline Cu_{1.8}S also shows a ZT of 0.5 at 673 K, higher than other p-type sulfide thermoelectric materials.

Nanoscale lead chalcogenides have also shown significant improvement in their thermoelectric performance. For example, the ZT of lead telluride (PbTe) can reach 2.2 at 915 K after introduction of nanoprecipitates through chemical doping (e.g. Sr- and Na-codoped PbTe, Ag- and Sb-codoped PbTe). PbS and PbSe also show a ZT over 1 or approaching 2 after introduction of nanoprecipitates, e.g. the nanocomposites of PbS—Bi₂S₃ (or Sb₂S₃, SrS and CaS) exhibit a ZT of 1.3 at 923 K. The nanoscale effects on the improvement of their thermoelectric performance are mainly due to the decrease in the thermal conductivity arising from increased phonon scattering.

Some nanoscale metal chalcogenides exhibit better thermoelectric performance than bulk analogues due to the significant decrease in thermal conductivity, and quantum confinement effects. Metal chalcogenide nanomaterials with tuneable size, morphology and composition can be prepared by various methods (e.g. ball-milling, sonochemistry, solvothermal and hydrothermal methods, and electro-deposition, etc.), of which wet-chemical approaches are more attractive in controlling morphology and particle size.

For example, Metha and co-workers used a microwave approach to prepare doped and undoped Bi₂Te₃ nanoplates with a ZT over 1 at 300 K (see R. J. Mehta, Y. L. Zhang, C. Karthik, B. Singh, R. W. Siegel, T. Borca-Tasciuc and G. Ramanath, Nat. Mater., 2012, 11, 233-240). Choi et al. prepared monodispersed Cu₂Se nanodiscs in oleyamine by using 1,3-dimethylimidazoline-2-selenone and copper acetate hydrate as Se- and Cu-precursors (see J. Choi, N. Kang, H. Y. Yang, H. J. Kim and S. U. Son, Chem. Mater., 2010, 22, 3586-3588.). Riha et al. developed another route to prepare Cu₂₋ₓSe nanoparticles by using trioctylphosphine (TOP) and trioctylphosphine oxide (TOPO) as ligands and solvents (see S. C. Riha, D. C. Johnson and A. L. Prieto, J. Am. Chem. Soc., 2011, 133, 1383-1390.). Ibáñez et al. prepared core-shell PbTe@PbS nanocrystals in organic solvent at high temperature and obtained a ZT of 1.1 at 710 K (see M. Ibanez, R. Zamani, S. Gorsse, J. D. Fan, S. Ortega, D. Cadavid, J. R. Morante, J. Arbiol and A. Cabot, ACS Nano, 2013, 7, 2573-2586).

Another potential application of metal chalcogenide nanomaterials is in solar cells which can directly convert energy of light into electricity. For example, nanostructured lead chalcogenides can be used to fabricate quantum dots sensitized solar cells (QDSSCs) to achieve high conversion efficiency (see Z. Ning, et al., Nat. Mater. 2014, 13, 822; C. H. Chuang, P. R. Brown, V. Bulovic, M. G. Bawendi, Nat. Mater. 2014, 13, 796). Copper chalcogenides can serve as excellent counter electrodes of QDSSCs where polysulfide electrolytes are used with enhanced electrochemical performance owing to their super catalytic activity for the reduction of polysulfide (see Z. S. Yang, et al., Adv. Energy Mater. 2011, 1, 259; Y. Jiang, et al., Nano. Lett. 2014, 14, 365). They show lower resistance and higher electrocatalytic activity towards the redox reaction of polysulfide, in comparison with the conventional noble counter electrodes (Pt or Au) which can be passivated by sulfur-containing (S²⁻ or thiol) compounds.

Although the above known methods can produce uniform nanoparticles, factors including a complicated process, low yield, high cost, high temperature and/or use of organic solvents limit their commercial applications. In some applications, such as thermoelectric conversion, surface ligands have to be removed in order to improve the contact among nanostructures for better conductivity. Therefore, it is highly significant to develop cost effective approaches to synthesize chalcogenide nanomaterials, preferably on a relatively large scale. It is also highly significant to develop cost effective approaches to synthesize chalcogenide nanomaterials with particular desirable nanostructures.

There is a need for new or improved metal chalcogenide nanomaterials and/or new or improved methods or processes of synthesizing or preparing metal chalcogenide nanomaterials.

The reference in this specification to any prior publication (or information derived from the prior publication), or to any matter which is known, is not, and should not be taken as an acknowledgment or admission or any form of suggestion that the prior publication (or information derived from the prior publication) or known matter forms part of the common general knowledge in the field of endeavour to which this specification relates.

### SUMMARY

This Summary is provided to introduce a selection of concepts in a simplified form that are further described below in the Preferred Embodiments. This Summary is not intended to identify key features or essential features of the claimed subject matter, nor is it intended to be used to limit the scope of the claimed subject matter.

In one aspect there is provided a metal chalcogenide nanomaterial, preferably a binary and ternary metal chalcogenide nanomaterial. In non-limiting examples, the metal chalcogenide nanomaterial is bismuth, copper, lead, silver, indium, tin and/or antimony chalcogenide nanomaterial. In another aspect there is provided a method or process of synthesizing or preparing a metal chalcogenide nanomaterial, for example bismuth, copper, lead, silver, indium, tin and/or antimony chalcogenide nanomaterial. In another example aspect there is provided a method suitable for large-scale preparation of metal chalcogenide nanomaterials, for example for energy conversion applications.

In accordance with another example aspect, there is provided a liquid-based chemical method to prepare metal chalcogenide nanomaterials, preferably via an aqueous route, and also preferably without use of a surfactant. That is, the mixture, suspension or solution undergoing reaction is a liquid mixture, suspension or solution, most preferably aqueous-based. In further specific examples, the metal chalcogenide nanomaterials are formed or provided as nanostructures, such as for example nanoparticles, nanowires, nanotubes and/or nanosheets.

In another aspect, there is provided a method for producing metal chalcogenide nanomaterials, comprising the steps of: forming an aqueous solution of a chalcogen precursor, a reducing agent and a metal salt; mixing the aqueous solution for a duration of time at a reaction temperature; and, separating a produced metal chalcogenide nanomaterial from the aqueous solution. In a preferred example, the metal chalcogenide nanomaterial is produced without use of a surfactant.

According to a preferred example, the reaction temperature is between about 10° C. to about 40° C., inclusively. In another example, the reaction temperature is between about 10° C. to about 30° C., inclusively. In another example, the reaction temperature is between about 20° C. to about 30° C., inclusively. Preferably, the reaction temperature is about room temperature (i.e. about 20° C. to about 26° C.) Preferably, external heating is not used.

In another example, the produced metal chalcogenide nanomaterial has a formula of MₓE_{y}, where: M is Bi, Cu, Pb, Ag, In, Sn, or Sb; E is O, S, Se or Te when M is Cu, or E is S, Se or Te when M is Bi, Pb, Ag, In, Sn, or Sb; and 1≤x≤2 and 1≤y≤3.

In another example, the produced metal chalcogenide nanomaterial has a formula of MₓE_{y}, where: M is Bi, Cu or Pb; E is O, S, Se or Te when M is Cu, or E is S, Se or Te when M is Bi or Pb; and 1≤x≤2 and 1≤y≤3.

Most preferably, the metal salt is water soluble. In another example, the metal salt is selected from the group of a bismuth salt, a copper salt, a lead salt, a silver salt, an indium salt, a tin salt and an antimony salt, and the produced metal chalcogenide nanomaterial is bismuth, copper, lead, silver, indium, tin and/or antimony chalcogenide nanoparticles. In another example, the produced metal chalcogenide nanomaterial is bismuth chalcogenide nanoparticles, and the metal salt is a water soluble bismuth salt. Optionally, the bismuth salt is bismuth chloride and/or bismuth nitrate. In another example, the produced metal chalcogenide nanomaterial is copper chalcogenide nanoparticles, and the metal salt is a water soluble copper salt. Optionally, the copper salt is copper chloride, copper nitrate and/or copper sulfate. In another example, the produced metal chalcogenide nanomaterial is lead chalcogenide nanoparticles, and the metal salt is a water soluble lead salt. Optionally, lead salt is lead nitrate.

Preferably, the chalcogen precursor is water soluble. In further examples, the chalcogen precursor is a chalcogen powder, a chalcogen solution, a chalcogen-based powder or a chalcogen-based solution. In other examples, the chalcogen precursor is sulfur, selenium or tellurium. In other examples, the chalcogen precursor is selected from the group of sodium sulfide (Na₂S.9H₂O), ammonium sulfide [(NH₄)₂S], sodium selenite (Na₂SeO₃), sodium tellurite (Na₂TeO₃), selenium oxide (SeO₂), and tellurium oxide (TeO₂).

In another example, the reducing agent is sodium borohydride (NaBH₄). In other examples, the reducing agent is LiBH₄ and/or KBH₄. In another example, the ratio of the reducing agent to the chalcogen precursor is from between about 1:1 to about 100:1. Preferably, the duration of time is from about 1 minute to about 24 hours, inclusively. More preferably, the duration of time is from about 1 minute to about 12 hours, inclusively. Even more preferably, the duration of time is from about 1 minute to about 6 hours, inclusively. In another example, the produced metal chalcogenide nanomaterial is separated by centrifugation.

In another aspect, there is provided a method of converting metal chalcogenide nanoparticles into metal chalcogenide nanotubes or metal chalcogenide nanosheets, comprising the steps of: forming an aqueous mixture of a chalcogen precursor, a reducing agent and the metal chalcogenide nanoparticles in water; and forming metal chalcogenide nanotubes by stirring the aqueous mixture; or, forming metal chalcogenide nanosheets by not stirring the aqueous mixture.

In various examples, the method of converting is performed at a reaction temperature of between about 10° C. to about 40° C., inclusively, or between about 10° C. to about 30° C., inclusively, or between about 20° C. to about 30° C., inclusively. Most preferably, the method is performed at a reaction temperature that is about room temperature (i.e. about 20° C. to about 26° C.). Preferably, external heating is not used.

In another example, the metal chalcogenide nanotubes or nanosheets are separated by centrifugation. In another example, the nanoparticles are mostly formed into nanotubes or nanosheets within less than about 1 hour. Preferably, the nanoparticles are mostly formed into nanotubes or nanosheets within less than about 30 min. In another example, the nanoparticles are mostly formed into nanotubes or nanosheets within less than about 20 min.

In another example, the metal chalcogenide nanoparticles, used in the method of converting to nanosheets or nanotubes, are produced according to the previously described method of producing metal chalcogenide nanomaterial. In another example, a diameter of the formed nanotubes is tuned by selecting a size of the metal chalcogenide nanoparticles. In another example, a size of the formed nanosheets is tuned by selecting a reaction time without stirring. In another example, the stirring uses magnetic or mechanical stirring.

### BRIEF DESCRIPTION OF FIGURES

Example embodiments are apparent from the following description, which is given by way of example only, of at least one preferred but non-limiting embodiment, described in connection with the accompanying figures.

FIG. 1 illustrates an example method for synthesis of metal chalcogenide nanomaterial, demonstrated by the preparation of cuprous selenide nanoparticles from selenium powder and copper chloride in water.

FIG. 2 illustrates an example method for conversion of as-synthesized nanoparticles into nanotubes and/or nanosheets, demonstrated by the conversion of cuprous selenide nanoparticles into cuprous telluride nanotubes and/or nanosheets.

FIGS. 3a-c show Scanning Electron Microscope (SEM) images of different-sized cuprous selenide nanoparticles synthesized according to the example method illustrated in FIG. 1, showing the capability of the method in tuning nanoparticle size. FIG. 3d shows the x-ray diffraction (XRD) patterns of different sized example nanoparticles, showing a slight red-shift with increase of particle size.

FIGS. 4a-c show the SEM images, and FIG. 4d shows the XRD patterns, of example Cu₂O, Cu₂S, and Cu₂Te nanoparticles.

FIGS. 5a-c show the SEM images of example produced uniform bismuth sulphide, bismuth selenide and bismuth telluride nanoparticles; FIGS. 5d-f show the SEM images of example produced lead sulphide, lead selenide and lead telluride nanoparticles.

FIG. 6 presents SEM images of example obtained silver, tin and antimony chalcogenide nanoparticles.

FIGS. 7a-c show the SEM images, and FIG. 7d shows the XRD patterns, of example Cu₂Te nanosheets and nanotubes converted from Cu₂Se nanoparticles, according to the example method shown in FIG. 2.

FIGS. 8a-f show the SEM images of example size-tuneable Cu₂Te nanotubes made from different sized Cu₂Se nanoparticles, demonstrating the size dependence of nanotubes on the nanoparticle size.

FIGS. 9a-d show the SEM images of example Cu₂Te nanosheets made from different reaction times without mixing/stirring, showing the influence of reaction time and the importance of mixing/stirring in the formation of nanotubes.

FIGS. 10a-d show the XRD pattern, SEM, TEM and high-resolution TEM images of ternary example CuAgSe nanoparticles.

FIGS. 11a-d show the temperature dependence of electrical conductivity, Seebeck coefficient, thermal conductivity and ZT of an example pellet sintered from CuAgSe nanoparticles by a spark plasma sintering technique, demonstrating novel temperature-dependent metallic-n-p conductivity transition.

FIG. 12 shows the performance of quantum dots sensitized solar cells (QDSSCs) assembled with example counter electrodes fabricated from Cu₂Te nanoparticles (NP), nanotubes (NT) and nanosheets (NS), and Au, demonstrating the morphology dependent performance and their better performance than noble Au electrode.

FIG. 13 illustrates an example method for producing metal chalcogenide nanomaterial.

FIG. 14 illustrates an example method for conversion of metal chalcogenide nanoparticles into nanotubes and/or nanosheets.

### PREFERRED EMBODIMENTS

The following modes, given by way of example only, are described in order to provide a more precise understanding of the subject matter of a preferred embodiment or embodiments. In the figures, incorporated to illustrate features of an example embodiment, like reference numerals are used to identify like parts throughout the figures.

Example embodiments described herein provide a general method of synthesizing surfactant-free metal chalcogenide nanostructures, particularly, but not exclusively, bismuth, copper, lead, silver, tin, indium and/or antimony chalcogenide nanoparticles, nanowires, nanotubes and/or nanosheets in aqueous solution at room temperature (i.e. about 20° C. to about 26° C.), i.e. without necessarily requiring application of external heat to the reaction. The size, morphology and/or composition of the metal chalcogenide nanomaterials can be tuned by controlling the ratio between reducing agent and chalcogen precursor, the cationic and anionic precursor ratio, the reduction time, and/or stirring time, etc. The cationic precursors are water-soluble, and preferably air-stable, metal salts such as, for example, bismuth nitrate, bismuth chloride, copper chloride, copper nitrate, copper sulphate, lead nitrate, indium chloride, and/or antimony chloride. The anionic precursors are, for example, sodium sulphide, ammonium sulphide, sulfur, selenium, tellurium, sodium selenite, sodium tellurite, selenium oxide, and/or tellurium oxide, which can be dissolved in water, or can be reduced by a reducing agent in a water solution. The resultant nanostructures have great potential in conversion of heat into electricity over a wide temperature range, e.g. bismuth selenide or telluride nanomaterials can be used for low-temperature heat conversion, lead selenide and telluride can be used in mid-temperature ranges, and cuprous selenide can be used at high-temperature ranges.

In one embodiment there is provided an environmentally friendly and relatively low cost method for room temperature preparation of, as non-limiting examples, bismuth, copper, lead, silver, tin, indium, and/or antimony chalcogenide nanomaterials, which can be performed on a large scale. The preferred method provides an aqueous route without use of a surfactant, and the resultant nanomaterials are tunable in size, morphology and/or crystallinity. The resultant nanomaterials can be applied for conversion of heat into electricity.

In an example there is provided a method of synthesizing bismuth chalcogenide nanomaterials from air-stable and water-soluble bismuth salts, including bismuth chloride and/or bismuth nitrate which can be well dissolved in water, for example at low pH. In another example there is provided a method of synthesizing copper chalcogenide nanomaterials from air-stable and water-soluble copper salts including copper chloride, copper nitrate and/or copper sulfate. These copper salts can be well dissolved in water under neutral conditions. In another example there is provided a method of synthesizing lead chalcogenide nanomaterials by using air-stable and water-soluble lead nitrate as a precursor. In another example there is provided a method of synthesizing silver chalcogenide nanomaterials from water-soluble silver salts such as silver nitrate and silver acetate. In another example there is provided a method of synthesizing tin chalcogenide nanomaterials from water-soluble tin salts such as tin (II) chloride, and tin (II) acetate.

In another example there is provided a method of synthesizing bismuth, copper, lead, silver, indium, tin and/or antimony chalcogenide nanomaterials, by using sodium borohydride (NaBH₄) as a reducing agent. Other reducing agents are possible such as LiBH₄, and KBH₄. The ratio of NaBH₄ to chalcogen precursor is varied from between about 1:1 to about 100:1, depending on the precursor type and desired product.

In another example there is provided a method of converting zero dimensional (0D) nanoparticles into one dimensional (1D) or two dimensional (2D) nanostructures. In another example there is provided a method of synthesizing metal chalcogenide nanotubes from prepared nanoparticles through an ion exchange process under magnetic or mechanical mixing or stirring. In another example there is provided a method of synthesizing metal chalcogenide nanosheets from prepared nanoparticles without mixing or stirring. In another example there is provided a method of synthesizing metal chalcogenide nanomaterials at room temperature (i.e. about 20° C. to about 26° C.) within a reaction time ranging from about 1 minute to about 48 hours, depending on requirements for the size and morphology of final nanomaterials.

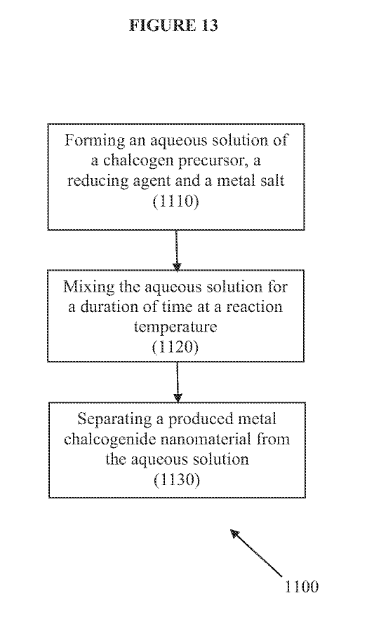

Referring to FIG. 13, there is provided a method 1100 for producing metal chalcogenide nanomaterial. Method 1100 includes the step of forming 1110 an aqueous solution of a chalcogen precursor, a reducing agent and a metal salt. Then mixing 1120 the aqueous solution for a duration of time at a reaction temperature, and separating 1130 a produced metal chalcogenide nanomaterial from the aqueous solution.

According to a preferred example, the metal chalcogenide nanomaterial is produced without use of a surfactant. According to another example, the reaction temperature is between about 10° C. to about 40° C., inclusively. In another example, the reaction temperature is between about 10° C. to about 30° C., inclusively. In another example, the reaction temperature is between about 20° C. to about 30° C., inclusively. Preferably, the reaction temperature is about room temperature (i.e. about 20° C. to about 26° C.). Preferably, external heating is not used or applied to the reaction.

In another example, the produced metal chalcogenide nanomaterial has a formula of MₓE_{y}, where: M is Bi, Cu, Pb, Ag, In, Sn, or Sb; E is O, S, Se or Te when M is Cu, or E is S, Se or Te when M is Bi, Pb, Ag, In, Sn, or Sb; and 1≤x≤2 and 1≤y≤3.

In another example, the produced metal chalcogenide nanomaterial has a formula of MₓE_{y}, where: M is Bi, Cu or Pb; E is O, S, Se or Te when M is Cu, or E is S, Se or Te when M is Bi or Pb; and 1≤x≤2 and 1≤y≤3.

Preferably, the metal salt is water soluble. In another example, the metal salt is selected from the group of a bismuth salt, a copper salt, a lead salt, a silver salt, a tin salt, an indium salt and an antimony salt, and the produced metal chalcogenide nanomaterial is bismuth, copper, lead, silver, indium, tin and/or antimony chalcogenide nanoparticles. In another example, the produced metal chalcogenide nanomaterial is bismuth chalcogenide nanoparticles, and the metal salt is a water soluble bismuth salt. Optionally, the bismuth salt is bismuth chloride and/or bismuth nitrate. In another example, the produced metal chalcogenide nanomaterial is copper chalcogenide nanoparticles, and the metal salt is a water soluble copper salt. Optionally, the copper salt is copper chloride, copper nitrate and/or copper sulfate. In another example, the produced metal chalcogenide nanomaterial is lead chalcogenide nanoparticles, and the metal salt is a water soluble lead salt. Optionally, lead salt is lead nitrate. In another example, the produced metal chalcogenide nanomaterial is antimony chalcogenide nanoparticles, and the metal salt is a water soluble antimony salt. Optionally, the antimony salt is antimony chloride.

Preferably, the chalcogen precursor is water soluble. In further examples, the chalcogen precursor is a chalcogen, a chalcogen powder, a chalcogen solution, a chalcogen-based powder or a chalcogen-based solution. In other examples, the chalcogen precursor is sulfur, selenium or tellurium. In other examples, the chalcogen precursor is selected from the group of sodium sulfide (Na₂S.9H₂O), ammonium sulfide [(NH₄)₂S], sodium selenite (Na₂SeO₃), sodium tellurite (Na₂TeO₃), selenium oxide (SeO₂), and tellurium oxide (TeO₂).

In another example, the reducing agent is sodium borohydride (NaBH₄). In another example, the molar ratio of the reducing agent to the chalcogen precursor is from between about 1:1 to about 100:1. Preferably, the duration of time is from about 1 minute to about 24 hours, inclusively. More preferably, the duration of time is from about 1 minute to about 12 hours, inclusively. Even more preferably, the duration of time is from about 1 minute to about 6 hours, inclusively. In another example, the produced metal chalcogenide nanomaterial is separated by centrifugation.

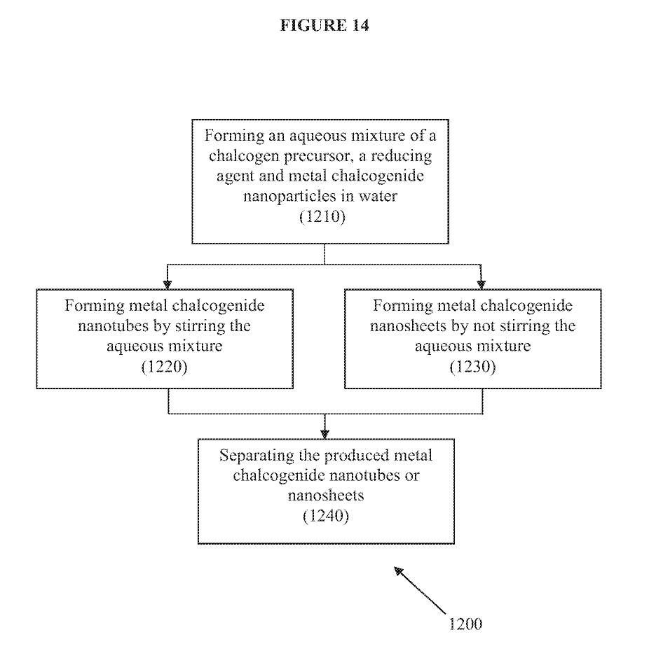

Referring to FIG. 14, in another example form, there is provided an aqueous-based method 1200 of converting metal chalcogenide nanoparticles into metal chalcogenide nanotubes or metal chalcogenide nanosheets. Method 1200 includes the step of forming 1210 an aqueous mixture of a chalcogen precursor, a reducing agent and the metal chalcogenide nanoparticles in water. Then forming 1220 metal chalcogenide nanotubes by stirring the aqueous mixture, or forming 1230 metal chalcogenide nanosheets by not stirring the aqueous mixture.

In various examples, the method of converting is performed at a reaction temperature of between about 10° C. to about 40° C., inclusively, or between about 10° C. to about 30° C., inclusively, or between about 20° C. to about 30° C., inclusively. Most preferably, the method is performed at a reaction temperature that is about room temperature (i.e. about 20° C. to about 26° C.). Again, preferably, external heating is not used.

In another example, the metal chalcogenide nanotubes or nanosheets are separated at step 1240 by centrifugation. In another example, the nanoparticles are mostly, or at least substantially, formed into nanotubes or nanosheets within less than about 1 hour. Preferably, the nanoparticles are mostly, or at least substantially, formed into nanotubes or nanosheets within less than about 30 min. In another example, the nanoparticles are mostly, or at least substantially, formed into nanotubes or nanosheets within less than about 20 min.

In another example, the metal chalcogenide nanoparticles, used in the method 1200 of converting to nanosheets or nanotubes, are produced according to the previously described method 1100 of producing metal chalcogenide nanomaterial. In another example, a diameter of the formed nanotubes is tuned by selecting a size of the metal chalcogenide nanoparticles. In another example, a size of the formed nanosheets is tuned by selecting a reaction time without stirring. In another example, the stirring uses magnetic or mechanical stirring.

Embodiments provide an environmentally friendly and relatively low-cost method for preparation of bismuth, copper, lead, silver, tin, indium and/or antimony chalcogenide nanomaterials. There are several distinct advantages over conventional preparation approaches, for example: (1) water serves as solvent and no surfactant is used; (2) there are many options for metal precursors and chalcogen precursors; (3) preparation can be carried out at room temperature, and the reaction is relatively fast; (4) the method can be scaled up for broad applications; (5) the size, shape, composition and/or crystallinity of resultant products are tuneable.

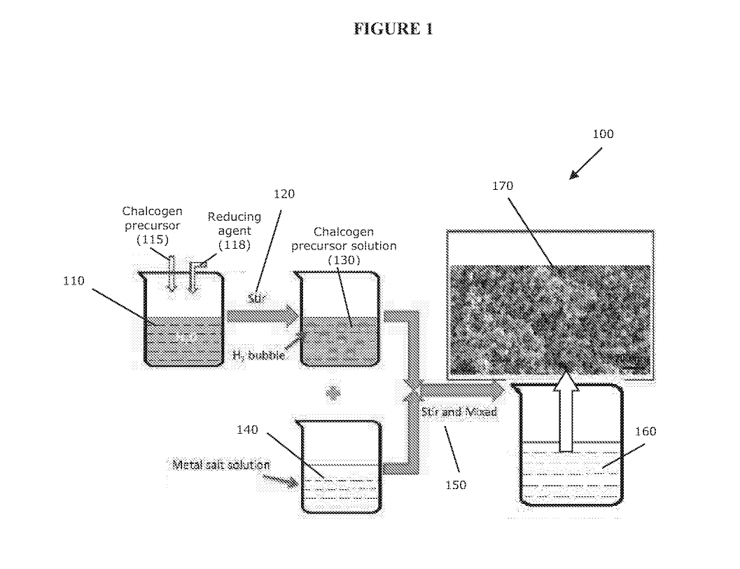

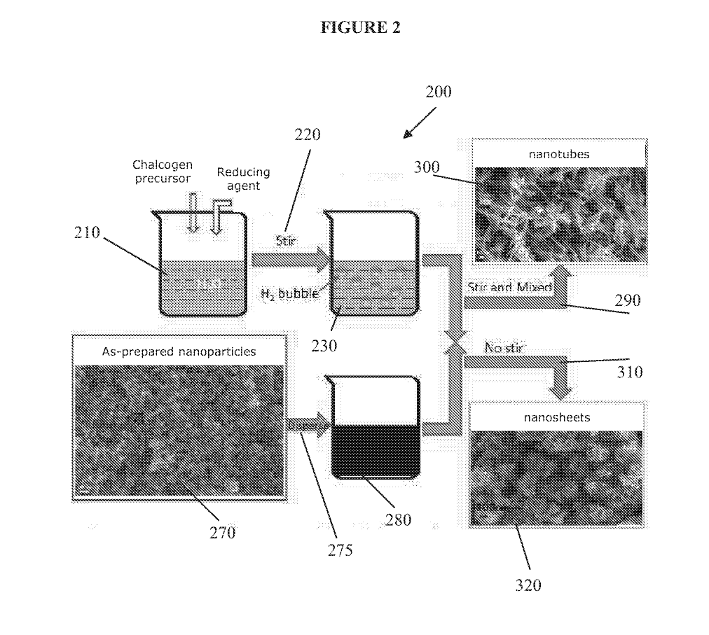

FIG. 1 and FIG. 2 show the typical steps for synthesis and structural conversion of bismuth, copper, lead, silver, tin, indium and/or antimony chalcogenide nanomaterials. The chalcogenide nanomaterials are formed or provided as nanostructures, and can be provided in a variety of one-dimensional, two-dimensional and/or three-dimensional shapes or geometries, such as nanoparticles, nanowires, nanotubes and/or nanosheets. Preferred embodiments are an initial synthesis as nanoparticles, which can then be used to convert further nanoparticles to nanotubes and/or nanosheets. The method is a cost-effective approach for preparing chalcogenide nanomaterials, preferably metal chalcogenide nanomaterials that can be used for energy conversion.

Referring to FIG. 1, in another example form there is provided an aqueous-based method 100 to prepare metal chalcogenide nanostructures 170, such as bismuth, copper, lead, silver, tin, indium and/or antimony chalcogenide nanostructures, particularly nanoparticles. The method includes, at step 110, adding a chalcogen precursor 115 and a reducing agent 118 to water, then stirring at step 120 to form a chalcogen precursor aqueous solution 130. Dissolving a metal salt in water forms a metal salt aqueous solution 140. At step 150, the metal salt aqueous solution 140 is mixed with the chalcogen precursor aqueous solution 130 for a duration of time at a reaction temperature, preferably at or about room temperature (i.e. about 20° C. to about 26° C.). Alternatively, the reaction temperature can be between about 10° C. to about 40° C., inclusively, between about 10° C. to about 30° C., inclusively, or between about 20° C. to about 30° C., inclusively. A product 170 can then be separated from the resulting solution 160. For example separating the product 170 could occur by centrifugation, and then washing with Milli-Q water for a few times, and then drying under vacuum to a constant weight, to produce product 170, which is a metal, for example bismuth, copper, lead, silver, indium, tin and/or antimony, chalcogenide nanomaterial 170, for example in the form of nanoparticles, depending on the type of metal salt used.

Referring to FIG. 2, in another example form there is provided an aqueous-based method 200 to convert metal chalcogenide nanoparticles 170 (i.e. 0D nanoparticles) into 1D or 2D nanostructures, for example nanotubes 300 or nanosheets 320, or nanowires if the diameter of the nanotubes is small or filled with material. The preparation of 1D or 2D nanostructures includes, at step 210, adding a chalcogen precursor and a reducing agent to water, then stirring at step 220 to form a chalcogen precursor aqueous solution 230. Previously prepared nanoparticles 270 are dispersed at step 275 in a volume of water to form an aqueous suspension of nanoparticles 280. The chalcogen precursor aqueous solution 230 is then mixed with the aqueous suspension of nanoparticles 280. If the mixture 230, 280 is stirred at step 290 for a duration of time then nanotubes 300 are formed, for example which can be separated by centrifugation, and the resultant nanotubes washed a few times with Milli-Q water, and then dried under vacuum to a constant weight. Alternatively, if the mixture 230, 280 is not stirred for a duration of time (i.e. no stirring step 310), then nanosheets 320 are formed, for example which can be separated by centrifugation, and the resultant nanosheets washed a few times with Milli-Q water, and then dried under vacuum to a constant weight.

Metal chalcogenide nanomaterials, for example bismuth, copper, lead, silver, tin, indium and/or antimony chalcogenide nanomaterials, have diverse applications ranging from energy to biomedical fields. The results described herein demonstrate that the nanomaterials can be used for energy applications, such as conversion of heat/light into electricity.

Embodiments include the preparation of 0D metal chalcogenide nanoparticles, and the preparation of associated 1D and 2D nanostructures. 0D nanoparticles were prepared by the reaction of water-soluble metal salts with chalcogen precursor in aqueous solution at room temperature, i.e. about 20° C. to about 26° C., (see FIG. 1). Other temperatures are possible, for example a reaction temperature between about 0° C. to about 100° C., inclusively; but preferably the reaction temperature is relatively low at between about 10° C. to about 40° C., inclusively, between about 10° C. to about 30° C., inclusively, or between about 20° C. to about 30° C., inclusively.

The preferred reaction temperature is at or about room temperature range, which also provides a significant advantage in that external heating is not required, or at least is optional. Typically, a chalcogen precursor was mixed with a reducing agent in water solution until it was completely, or substantially, dissolved. Metal salts were dissolved, or substantially dissolved, in water, and then quickly added into the chalcogen solution under vigorous stirring. The mixture was stirred for a duration of time and the resultant precipitates were separated by centrifugation. Example stirring or mixing times are from about 1 minute to about 48 hours; from about 1 minute to about 24 hours; from about 1 minute to about 12 hours; from about 1 minute to about 6 hours; from about 1 minute to about 3 hours; from about 1 minute to about 1 hour; from about 1 minute to about 30 minutes; or from about 1 minute to about 10 minutes. After washing for a few cycles, the precipitates were dried under vacuum.

The as-synthesized 0D nanoparticles were then used as a precursor to prepare 1D and 2D nanostructures according to the example method presented in FIG. 2. The freshly synthesized nanoparticles were suspended in water solution. The chalcogen precursor solution was prepared by the same process as previously described, and then added into the nanoparticle suspension under vigorous stirring. The mixture was either continuously stirred or stopped without stirring. The formed 1D or 2D nanostructures were separated by centrifugation, and can be purified by the same process as described previously.

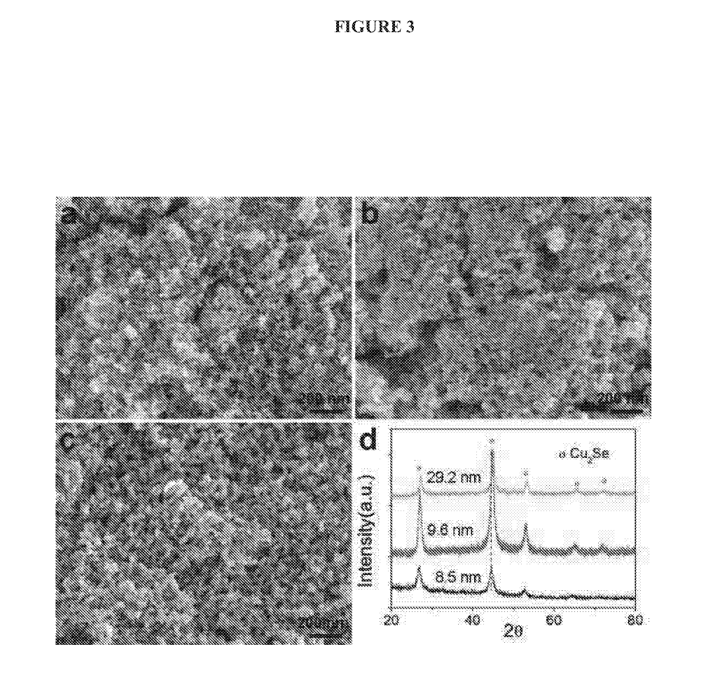

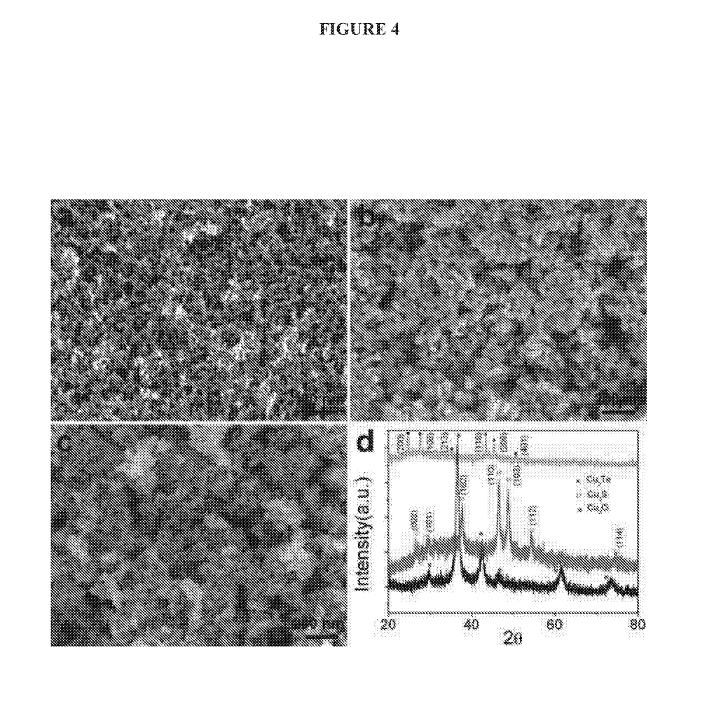

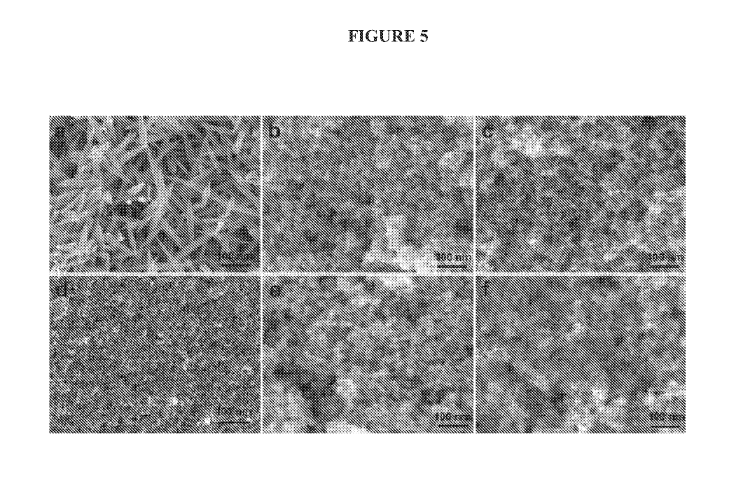

FIG. 3 shows SEM images and XRD patterns of different-sized cuprous selenide nanoparticle powders. The results demonstrate that the particle size can be tuned from about 8 nm to about 30 nm by simply controlling the reduction time of chalcogen precursor between about 1 min to about 120 min; between about 10 min to about 60 min; or between about 15 min to about 30 min. The absence of other peaks in their XRD patterns shows the pure phase of Cu₂Se. In order to test general applicability, other copper, bismuth, lead, silver, tin, indium and antimony chalcogenide nanoparticles were prepared using a similar procedure. FIG. 4 shows SEM images and the XRD patterns of Cu₂O, Cu₂S and Cu₂Te nanoparticles. FIG. 5 shows SEM images of bismuth chalcogenide and lead chalcogenide nanomaterials, respectively. The results clearly show uniformity of morphology and particle size, demonstrating the general applicability of the method to a variety of different metal chalcogenide nanoparticles.

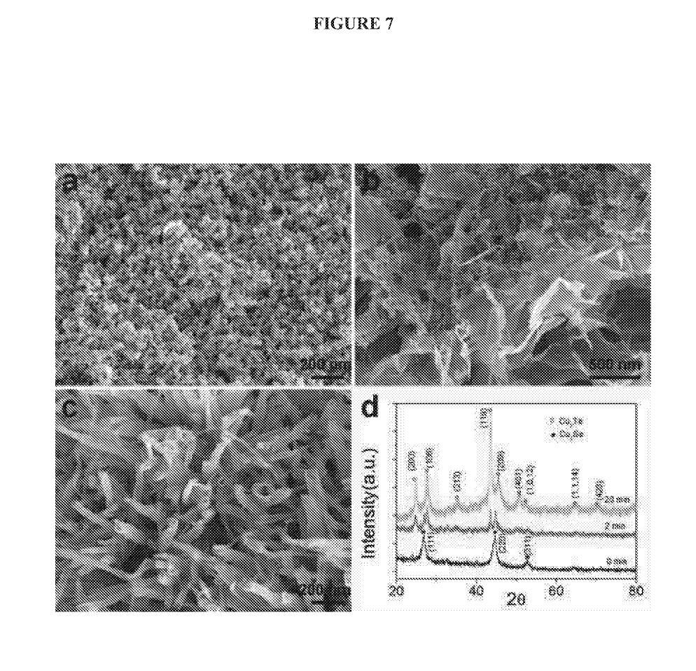

Furthermore, the as-synthesized nanoparticles can be used as precursors to prepare 1D and 2D nanostructures. FIG. 7 shows SEM images and XRD patterns of Cu₂Se nanoparticles, intermediate and final product. The results demonstrate the complete conversion of Cu₂Se nanoparticles into Cu₂Te nanotubes within less than 30 min, for example typically between about 10 min to about 30 min, and more typically within less than about 20 min. The intermediate is a mixture of a small amount of nanoparticles and a majority of nanosheets (FIG. 7b). The intermediate nanosheets can be rolled into nanotubes under magnetic stirring (FIG. 7c).

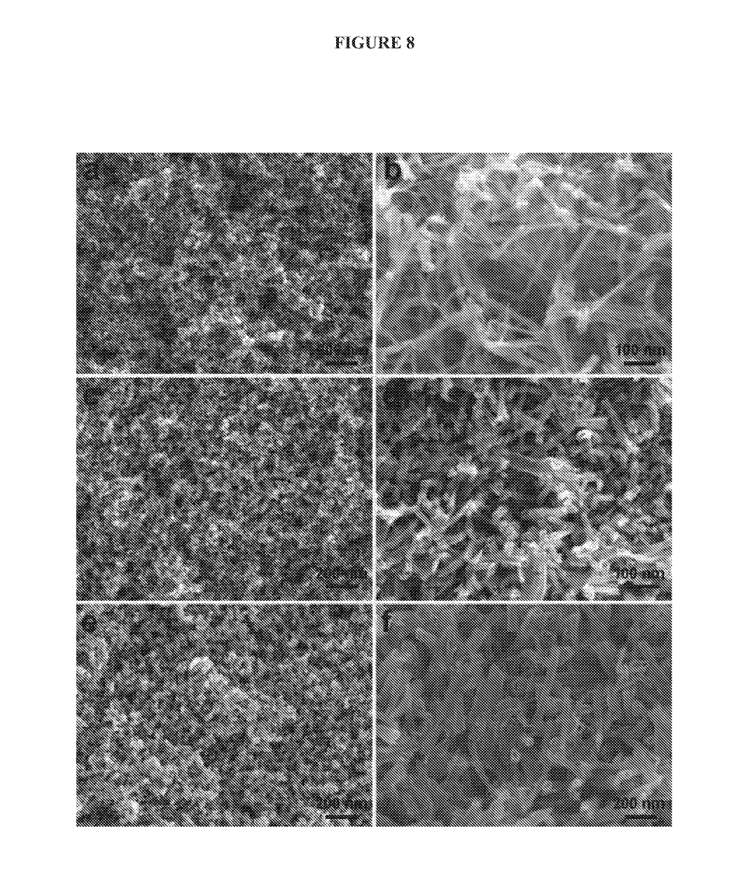

In order to investigate the diameter dependence of Cu₂Te nanotubes on the size of nanoparticle precursor, different sized Cu₂Se nanoparticles were selected as precursors, and similar structure conversion reactions were performed. FIG. 8 shows SEM images of starting nanoparticles (FIGS. 8a, 8c and 8e) and the corresponding nanotubes (FIGS. 8b, 8d and 8f, respectively), clearly showing the strong diameter dependence on the size of initial nanoparticles. Thus, the thickness of nanosheets and the diameter of nanotubes can be tuned by manipulating the size of precursor nanoparticles.

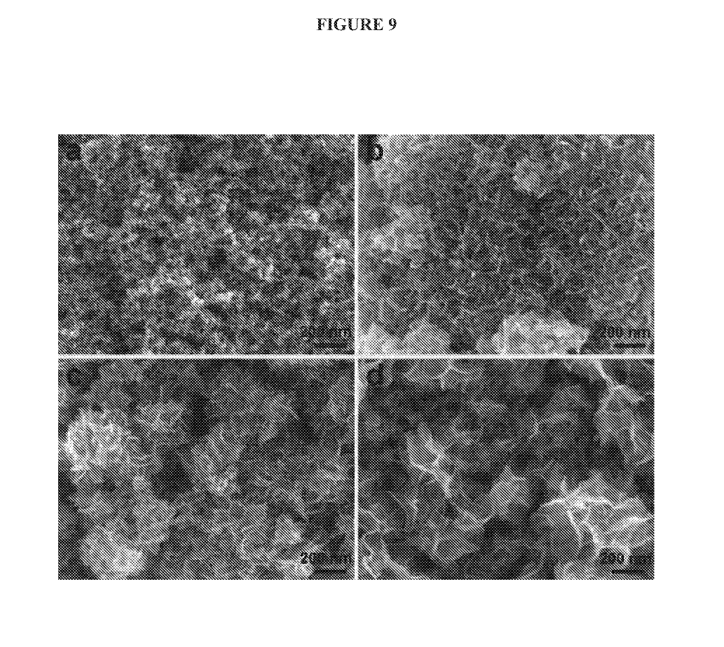

The importance of stirring has also been investigated during structural transformation, and FIG. 9 shows SEM images of initial nanoparticles and the conversion products at different times without magnetic stirring. There are only nanosheets formed without stirring, and the size of nanosheets increases with increasing reaction time (Figures a-d are time ordered). Therefore, nanosheets or nanotubes can be prepared by simply stirring or not stirring a reaction mixture. The size of the formed nanosheets can be tuned by selecting a reaction time without stirring.

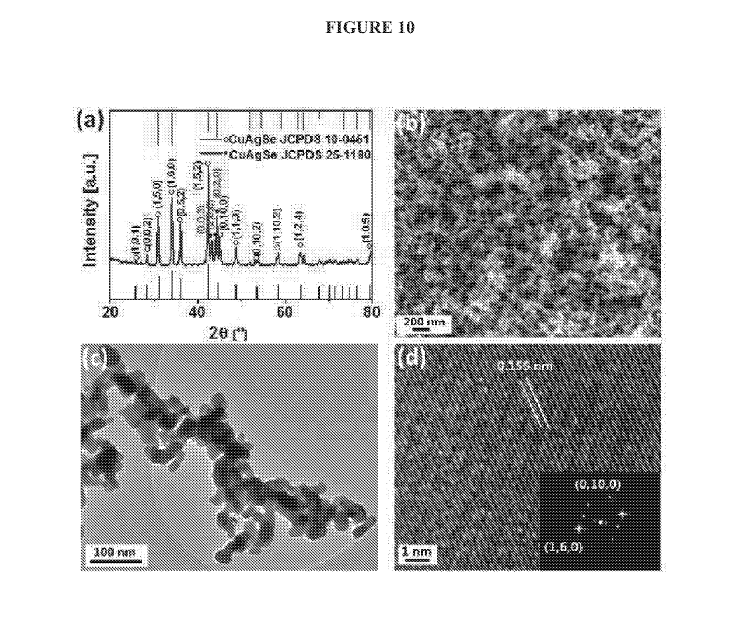

In addition to binary chalcogenide nanostructures, this novel aqueous approach is capable of preparing ternary chalcogenides such as CuAgSe, CuAgS, CuSe₁₋ₓSₓ, Bi₂Se₃₋ₓTeₓ nanostructures on a large scale. FIGS. 10a-d show the XRD pattern, SEM, TEM and high-resolution TEM images of ternary CuAgSe nanoparticles.

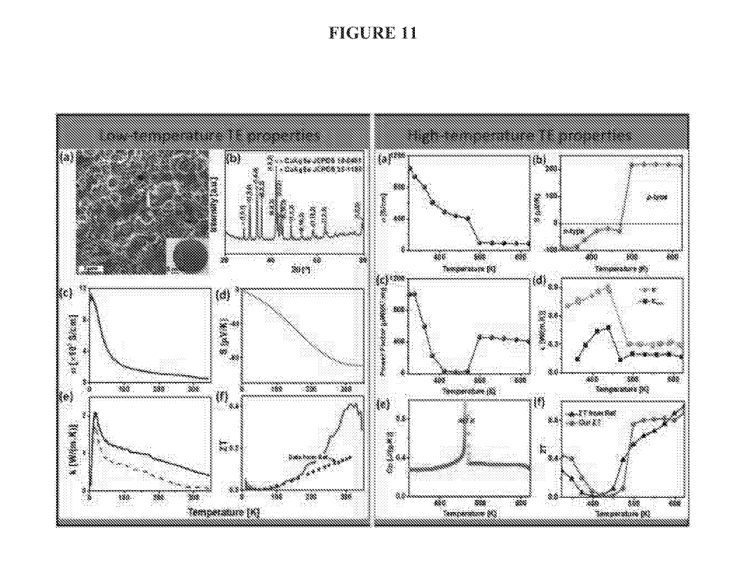

A significant advantage of present embodiments is that excellent, or at least well-formed, nanostructures can be synthesized in large scale for diverse applications. By way of example, an application in thermoelectric technology is presented. FIGS. 11a-d show the temperature dependence of electrical conductivity, Seebeck coefficient, thermal conductivity and ZT of an example pellet sintered from CuAgSe nanoparticles by a spark plasma sintering technique. A novel temperature-dependent conductivity transition was observed in the pallet, i.e. the conductivity transferred from metallic conducting through n-type semiconducting into p-type semiconducting with the increase of temperature from 3K to 600 K. The ZT value is higher the literature reports (see S. Ishiwata, Y. Shiomi, J. S. Lee, M. S. Bahramy, T. Suzuki, M. Uchida, R. Arita, Y. Taguchi, Y. Tokura, Nat. Mater. 2013, 12, 512-517.) demonstrating the importance of nanostructures in enhancing the thermoelectric performance.

Thus, there is provided an environmentally friendly and economic approach to preparing metal chalcogenide nanostructures, such as bismuth, copper, lead, silver, tin, indium and/or antimony chalcogenide nanostructures, with tuneable size and/or morphology for diverse applications, as further demonstrated by the following more specific examples.

### FURTHER EXAMPLES

The following examples provide more detailed discussion of particular embodiments. The examples are intended to be merely illustrative and not limiting to the scope of the present invention.

### Example 1: Preparation of Size Tuneable Cu₂Se Nanoparticles

In a typical synthesis indicative of various examples, 3.16 g (40 mmol) of Se powder was suspended in 400 mL of water (an example of an aqueous solution or suspension including a chalcogen precursor), followed by addition of 4.5 g (120 mmol) of NaBH₄ (an example of an aqueous solution including a reducing agent). The mixture was stirred for 15 min to form a colourless solution, then 13.6 g (80 mmol) of CuCl₂ solution (an example of an aqueous solution including a metal salt) was quickly added into the mixture under vigorous stirring. The mixture was stirred for another 10 min and the resultant black precipitates were separated by centrifugation and washed for several times with Milli-Q water. The black products are characterized to be pure Cu₂Se nanoparticles with an average size of 8.5 nm (FIGS. 3a and 3d). 9.6 nm and 29.2 nm sized Cu₂Se nanoparticles were prepared in a similar way, except prolonging reduction time from about 15 min to about 30 min (9.6 nm, FIG. 3b), or to about 60 min (29.2 nm, FIG. 3c). All the nanopowders were dried to a constant weight and kept under vacuum.

### Example 2: Preparation of Cu₂Te, Cu₂S, Cu₂O Nanoparticles

Cu₂Te nanoparticles were prepared in a similar way, 10 mmol of Te powder was mixed with 30 mmol of NaBH₄ in 40 mL of water. After the Te powder was completely reduced, 20 mmol of CuCl₂ solution was quickly added into the purple Te-precursor solution under magnetic stirring. The resultant black precipitates were separated by centrifugation and washed with water for a few times. FIG. 4a is the SEM image of resultant product, clearly showing the uniform size of nanoparticles.

Cu₂S nanoparticles were prepared by using Na₂S.9H₂O as precursor. Equal molar Na₂S.9H₂O and NaBH₄ were dissolved in 40 mL water, and then 10 mL of CuCl₂ solution (0.2 M) was added into the mixture. The resultant precipitates were collected and purified by the above procedure. FIG. 4b shows the SEM image of obtained nanoparticles. It should be noted that Cu₂O nanoparticles rather than Cu₂S were obtained when more NaBH₄ was used. FIG. 4c shows the SEM image of Cu₂O nanoparticles made from 5 times the NaBH₄. Their XRD patterns shown in FIG. 4d demonstrate the absence of other crystal phases and the high purity of the produced nanoparticles.

### Example 3: Synthesis of Bi₂E₃ and PbE (E=S, Se, and Te) Nanoparticles

In order to test general applicability of the method, a similar procedure was used to prepare bismuth chalcogenide and lead chalcogenide nanoparticles. Typically, 1 mmol of Bi(NO₃)₃.5H₂O was dissolved in 9 mL of H₂O and 1 mL of HNO₃ (70%) (i.e. an acid) to form a clear solution. 1.5 mmol of Se (or Te) powder and 3 mmol of NaBH₄ were dissolved in 10 mL of H₂O. After the Se (or Te) was completely dissolved, Bi-solution was quickly added into Se (or Te)-precursor solution. After stirring for about 10 min, the resultant precipitates were collected by centrifugation and washed with water for a few times. Bi₂S₃ nanoparticles were prepared in a similar way as for Cu₂S nanoparticles, except without NaBH₄. By controlling the amount of HNO₃, we can get well crystallined shuttle-like Bi₂S₃ nanorods. FIG. 5(a-c) presents SEM images of the obtained bismuth sulphide, bismuth selenide and bismuth telluride nanostructures.

Lead chalcogenide nanoparticles were prepared by a similar procedure. The only difference is that no acid was used. Typically, 1 mmol of Se (or Te) powder and 2 mmol of NaBH₄ were dissolved in 10 mL H₂O. After the Se (or Te) was completely dissolved, 5 mL of Pb(NO₃)₂ solution (0.2 M) was added. The resultant precipitates were collected by centrifugation and washed with water for a few times. FIG. 5 (d-f) shows SEM images of the obtained lead sulphide, lead selenide and lead telluride nanoparticles. Uniform nanoparticles were obtained successfully, demonstrating the general applicability of the approach.

### Example 4: Synthesis of Ag₂E, SnE and Sb₂E₃ (E=S, Se, and Te) Nanoparticles

The general applicability of this aqueous method is further demonstrated by the preparation of silver, tin and antimony chalcogenide nanoparticles. In the preparation of Ag₂Se and Ag₂Te nanoparticles, 1 mmol Se (or Te) powder was completely reduced by 2 mmol NaBH₄ in 10 mLH₂O; and then quickly added into 20 mL AgNO₃ water solution (2 mmol AgNO₃). The resultant black precipitates were separated by centrifugation, then washed with Milli-Q water for several times, and dried under a vacuum to constant weight. Tin and antimony selenites and tellurites were prepared by the similar way except 3 mL concentrated HCl was added into SnCl₂ or SbCl₃ solution to prevent the hydrolysis of Sn²⁺ and Sb³⁺ ions.

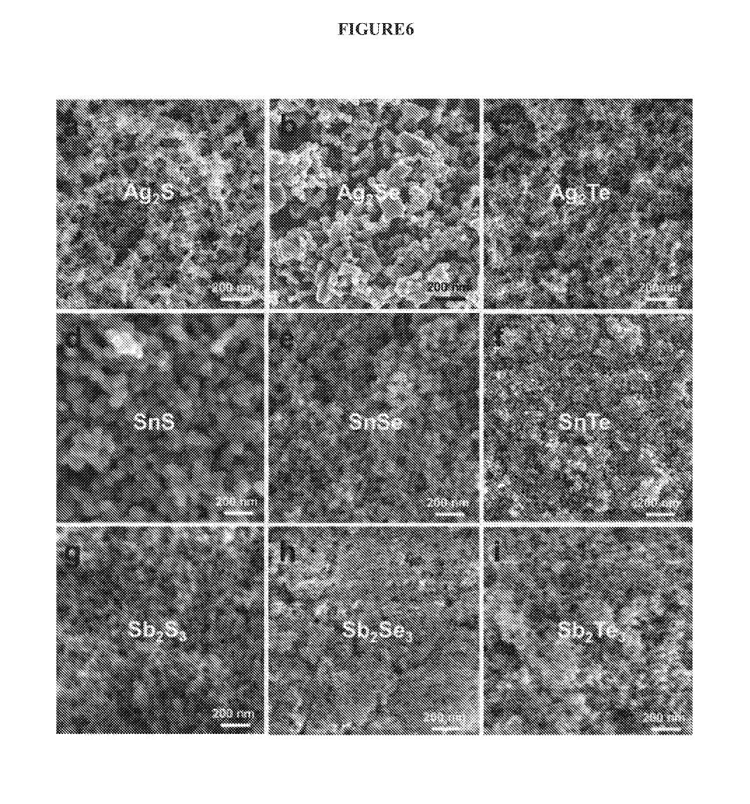

During the preparation of AO nanoparticles, 1 mmol Na₂S was dissolved in 10 mL H₂O, and then mixed with 2 mmol AgNO₃ in 20 mL H₂O under stirring. The resultant precipitates were separated and purified by the similar procedure. For the preparation of SnS and Sb₂Se₃ nanoparticles, 3 mL concentrated HCl was also used to prevent the hydrolysis of SnCl₂ or SbCl₃. FIG. 6 presents SEM images of the obtained silver, tin and antimony chalcogenide nanoparticles.

### Example 5: Synthesis of 1D Cu₂Te Nanotubes

The as-synthesized metal chalcogenide nanoparticles can be converted into 1D nanostructures (e.g. nanotubes or nanowires), as exemplified by using Cu₂Se nanoparticles. Firstly, 1 mmol of Te powder was dispersed in 100 mL of water, and then excessive NaBH₄ (26 mmol) was added to form a colourless solution. Then, 207 mg of Cu₂Se nanoparticles (29.2 nm) were dispersed into 10 mL of H₂O and added into freshly prepared Na₂Te solution under vigorous stirring. The mixture was stirred and intermediates were taken out at different times. The samples were separated by centrifugation and washed by water. FIG. 7 shows SEM images and XRD patterns of the initial Cu₂Se nanoparticles, and samples collected at 2 min and 20 min, showing the conversion of Cu₂Se nanoparticles into Cu₂Te nanotubes via rolling up of intermediate nanosheets.

In order to better understand the conversion mechanism, 7 nm, 8 nm, and 29 nm Cu₂Se nanoparticles were used as precursors to repeat the conversion reaction. The resultant nanotubes have an average diameter of about 14 nm, 15 nm and 52 nm, respectively. The SEM images of initial nanoparticles and the corresponding nanotubes are shown in FIG. 8, clearly demonstrating the strong diameter-dependence of nanotubes on the size of initial nanoparticles. Thus, the diameter of nanotubes can be tuned by selecting the size of the precursor nanoparticles.

### Example 6: Synthesis of 2D Cu₂Te Nanosheets

2D nanosheets were prepared by a similar method as applied for forming nanotubes. Typically, 1 mmol of Te powder was reduced by 26 mmol of NaBH₄ in 100 mL of H₂O with vigorous stirring. After the Te powder was completely reduced, 103 mg of freshly prepared Cu₂Se nanoparticles were dispersed in 100 mL of H₂O and then added into the precursor solution under vigorous stirring. Then stirring was immediately stopped and samples were collected at different times and purified for characterization. FIG. 9 shows SEM images of initial Cu₂Se nanoparticles and the products collected at 5 min, 20 min, and 3 hours. Only nanosheets were found without stirring, and their size increases with increasing reaction time. Thus, the size of the nanosheets can be tuned by selecting the reaction time.

### Example 7: Synthesis of Ternary Chalcogenide Nanoparticles

In addition to preparation of binary bismuth, copper, lead, silver, tin, indium and/or antimony chalcogenide nanomaterials, this method is also capable of preparing their ternary nanomaterials such as CuAgSe, CuAgS, Cu₂S₁₋ₓSeₓ, Cu₂Se₁₋ₓTeₓ, PbSe₁₋ₓSₓ, PbSe₁₋ₓTeₓ etc. In a typical synthesis, 3.16 g (40 mmol) Se powder and 4.54 g NaBH₄ were dispersed in 400 mL distilled water, and the mixture was stirred for 25 min under the protection of Ar at room temperature to form a colorless selenium precursor solution. 9.7 g (40 mmol) Cu(NO₃)₂.3H₂O and 6.8 g (40 mmol) AgNO₃ were completely dissolved in 400 mL distilled water, and then quickly added into the Se-precursor solution to form CuAgSe black precipitates. The black product was separated by centrifugation and washed with distilled water several times, and then dried to a constant weight in a vacuum. FIGS. 10a-d show the XRD pattern, SEM, TEM and high-resolution TEM images of resultant CuAgSe nanoparticles, demonstrating that the obtained CuAgSe nanoparticles has an uniform size and high crystalline.

### Example 8: Thermoelectric Properties of Metal Chalcogenide Nanostructures

The thermoelectric properties of metal chalcogenide nanostructures were characterized using pellets compressed from their nanostructure powders. A pellet made from CuAgSe nanoparticles was used as an example. Typically, 3 g of as-synthesized CuAgSe nanoparticles were loaded into a 20-mm graphite die, and then sintered at 430° C. for 10 min under argon atmosphere using a spark plasma sintering technique achieving 94% of bulk density. FIGS. 11 a-b in the left column shows the cross-section SEM image of sintered CuAgSe pellet and its XRD pattern. The pellet was then cut into pieces for the thermoelectric measurement. The low-temperature thermoelectric performance (i.e. from 3 K to 350 K) was tested on a physical properties measurement system (PPMS). FIGS. 11 c-f in the left column shows the Seebeck coefficient, electrical conductivity, and thermal conductivity, as well as the ZT values. The results demonstrate the higher ZT values of the samples produced according to present embodiments compared to those reported in the literature (see S. Ishiwata, Y. Shiomi, J. S. Lee, M. S. Bahramy, T. Suzuki, M. Uchida, R. Arita, Y. Taguchi, Y. Tokura, Nat. Mater. 2013, 12, 512-517). The high-temperature (i.e. from 323 K to 623 K) conductivity was measured from 323 K to 623 K, electrical conductivity and Seebeck coefficient of the pieces were measured with an Ozawa RZ2001i (Japan) instrument, and the thermal conductivity was calculated from k=DCₚρ, where D is the thermal diffusivity and measured by Netzsch LFA1000. Cₚ is the specific heat capacity and determined by differential scanning calorimetry and ρ is the density calculated from mass and volume. FIGS. 11a-f in the right column show temperature dependence of electrical conductivity, Seebeck coefficient, thermal conductivity and ZT. A novel temperature-dependent metallic-n-p conductivity transition was observed.

### Example 9: Fabrication of Counter Electrodes from Metal Chalcogenide Nanostructures

Another potential application of resultant metal chalcogenide nanostructures is in solar cells, serving as sensitizers and counter electrodes of quantum dots sensitized solar cells (QDSSCs). Cu₂Te nanoparticles, nanotubes and nanosheets were used to fabricate counter electrodes of QDSSCs. They were deposited on FTO substrates by the doctor blade technique and the formed films were annealed at 350° C. for 30 min in Ar atmosphere to remove the binder and enhance the contact between film and substrate. For comparison, Au electrodes were prepared by sputtering a layer of Au with 50 nm.

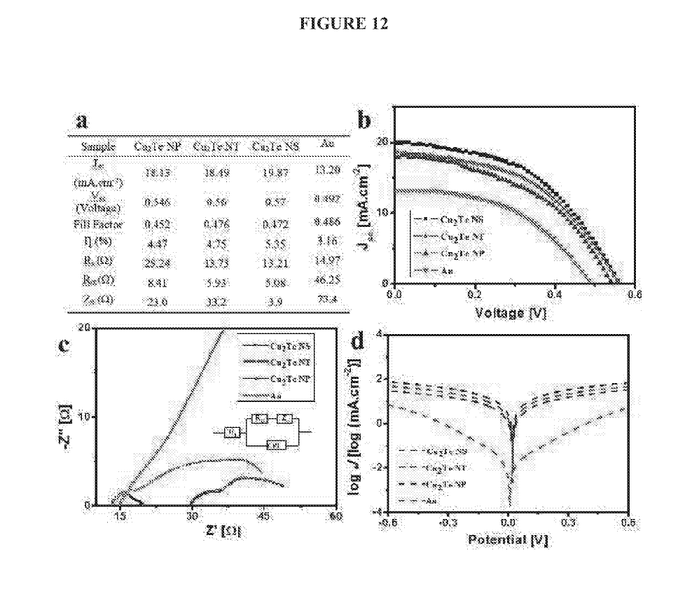

The solar cells were fabricated by assembling the counter electrodes (Cu₂Te NP, Cu₂Te NT, Cu₂Te NS, and Au) and CdSe/CdS-sensitized TiO₂ film electrode with a binder clip separated by a 60 μm thick spacer. A metal mask with a window area of 0.16 cm² was clipped onto the TiO₂ side to define the active area of the cell when testing. The polysulfide electrolyte was composed of 2 M Na₂S, 2 M S, and 0.2 M KCl in Milli-Q water. FIG. 12 shows the performance of QDSSCs assembled with example counter electrodes fabricated from Cu₂Te nanoparticles (NP), nanotubes (NT) and nanosheets (NS), and Au, demonstrating the morphology dependent performance and their better performance than noble Au electrode.

Optional embodiments may also be said to broadly include the parts, elements, steps and/or features referred to or indicated herein, individually or in any combination of two or more of the parts, elements, steps and/or features, and wherein specific integers are mentioned which have known equivalents in the art to which the invention relates, such known equivalents are deemed to be incorporated herein as if individually set forth.

Although a preferred embodiment has been described in detail, it should be understood that many modifications, changes, substitutions or alterations will be apparent to those skilled in the art without departing from the scope of the present invention.

1. A method for producing metal chalcogenide nanomaterials, comprising the steps of:
forming an aqueous solution of a chalcogen precursor, a reducing agent and a metal salt;
mixing the aqueous solution for a duration of time at a reaction temperature of between about 10° C. to about 40° C., inclusively; and,
separating a produced metal chalcogenide nanomaterial from the aqueous solution.

2. The method of claim 1, wherein the metal chalcogenide nanomaterial is produced without use of a surfactant.

3. The method of claim 1, wherein the reaction temperature is between about 10° C. to about 30° C., inclusively.

4. The method of claim 1, wherein the reaction temperature is between about 20° C. to about 30° C., inclusively.

5. The method of claim 1, wherein the reaction temperature is about room temperature.

6. The method of claim 5, wherein external heating is not used.

7. The method of claim 1, wherein the produced metal chalcogenide nanomaterial has a formula of MₓE_{y}, where:
M is Bi, Cu, Pb, Ag, In, Sn, or Sb;
E is O, S, Se or Te when M is Cu, or E is S, Se or Te when M is Bi, Pb, Ag, In, Sn, or Sb; and
1≤x≤2 and 1≤y≤3.

8. The method of claim 1, wherein the produced metal chalcogenide nanomaterial has a formula of MₓE_{y}, where:
M is Bi, Cu or Pb;
E is O, S, Se or Te when M is Cu, or E is S, Se or Te when M is Bi or Pb; and
1≤x≤2 and 1≤y≤3.

9. The method of claim 1, wherein the metal salt is water soluble.

10. The method of claim 1, wherein the metal salt is selected from the group of a bismuth salt, a copper salt, a lead salt, a silver salt, an indium salt, a tin salt and an antimony salt, and the produced metal chalcogenide nanomaterial is bismuth, copper, lead, silver, indium, tin and/or antimony chalcogenide nanoparticles.

11. The method of claim 1, wherein the produced metal chalcogenide nanomaterial is bismuth chalcogenide nanoparticles, and the metal salt is a water soluble bismuth salt.

12. The method of claim 11, wherein the bismuth salt is bismuth chloride and/or bismuth nitrate.

13. The method of claim 1, wherein the produced metal chalcogenide nanomaterial is copper chalcogenide nanoparticles, and the metal salt is a water soluble copper salt.

14. The method of claim 13, where the copper salt is copper chloride, copper nitrate and/or copper sulfate.

15. The method of claim 1, wherein the produced metal chalcogenide nanomaterial is lead chalcogenide nanoparticles, and the metal salt is a water soluble lead salt.

16. The method of claim 15, where the lead salt is lead nitrate.

17. The method of claim 1, wherein the chalcogen precursor is water soluble.

18. The method of claim 1, wherein the chalcogen precursor is a chalcogen powder, a chalcogen solution, a chalcogen-based powder or a chalcogen-based solution.

19. The method of claim 1, wherein the chalcogen precursor is sulfur, selenium or tellurium.

20. The method of claim 1, wherein the chalcogen precursor is selected from the group of sodium sulfide (Na₂S.9H₂O), ammonium sulfide [(NH₄)₂S], sodium selenite (Na₂SeO₃), sodium tellurite (Na₂TeO₃), selenium oxide (SeO₂), and tellurium oxide (TeO₂).

21. The method of claim 1, wherein the reducing agent is sodium borohydride (NaBH₄), LiBH₄, and/or KBH₄.

22. The method of claim 1, wherein the ratio of the reducing agent to the chalcogen precursor is from between about 1:1 to about 100:1.

23. The method of claim 1, wherein the duration of time is from about 1 minute to about 24 hours, inclusively.

24. The method of claim 1, wherein the duration of time is from about 1 minute to about 12 hours, inclusively.

25. The method of claim 1, wherein the duration of time is from about 1 minute to about 6 hours, inclusively.

26. The method of claim 1, wherein the produced metal chalcogenide nanomaterial is separated by centrifugation.

27. A metal chalcogenide nanomaterial, produced according to the method of claim 1.

28. A method of converting metal chalcogenide nanoparticles into metal chalcogenide nanotubes or metal chalcogenide nanosheets, comprising the steps of:
forming an aqueous mixture of a chalcogen precursor, a reducing agent and the metal chalcogenide nanoparticles in water; and
forming metal chalcogenide nanotubes by stirring the aqueous mixture; or,
forming metal chalcogenide nanosheets by not stirring the aqueous mixture.

29. The method of claim 28, wherein the method is performed at a reaction temperature of between about 10° C. to about 40° C., inclusively, or between about 10° C. to about 30° C., inclusively, or between about 20° C. to about 30° C., inclusively.

30. The method of claim 28, wherein the method is performed at a reaction temperature that is about room temperature.

31. The method of claim 30, wherein external heating is not used.

32. The method of claim 28, wherein the metal chalcogenide nanotubes or nanosheets are separated by centrifugation.

33. The method of claim 28, wherein the nanoparticles are mostly formed into nanotubes or nanosheets within less than about 1 hour.

34. The method of claim 28, wherein the nanoparticles are mostly formed into nanotubes or nanosheets within less than about 30 min.

35. The method of claim 28, wherein the nanoparticles are mostly formed into nanotubes or nanosheets within less than about 20 min.

36. The method of claim 28, wherein the metal chalcogenide nanoparticles are produced according to claim 1.

37. The method of claim 28, wherein a diameter of the formed nanotubes is tuned by selecting a size of the metal chalcogenide nanoparticles.

38. The method of claim 28, wherein a size of the formed nanosheets is tuned by selecting a reaction time without stirring.

39. The method of claim 28, wherein the stirring uses magnetic or mechanical stirring.

40. The method of claim 28, further including the metal chalcogenide nanomaterials being formed into a pellet.
